(19) United States
(12) Patent Application Publication
(10) Pub. No.: US 2004/0207395 A1
(43) Pub. Date: Oct. 21, 2004

(54) Eddy current-capacitance sensor for conducting film characterization

(76) Inventors: Moshe Sarfaty, Cupertino, CA (US); Ramaswamy Sreenivasan, Greenbelt, MD (US); Cuong Le, Morgan Hill, CA (US)

Correspondence Address: PATENT COUNSEL, APPLIED MATERIALS, INC., Legal Affairs Department, P.O. BOX 450A, Santa Clara, CA, 95052, US

(21) Appl. No.: 10/409,649

(22) Filed: Apr. 8, 2003

Related U.S. Application Data
(60) Provisional application No. 60/371,267, filed on Apr. 8, 2002.

(51) Int. Cl. G01B 7/06; G01R 33/12; G01N 27/72

(52) U.S. Cl. 324/230; 324/662; 324/234

(57) ABSTRACT

In a first aspect, a sensor enables the efficient measurement of conducting film thickness by providing a capacitance probe with an eddy current coil placed co-axially within the capacitance probe. The capacitance probe senses the proximity of the sensor to the conducting film, the proximity measurement enabling an eddy current detector coupled to the eddy current coil to measure the thickness of the conducting film. More specifically, the eddy current coil is excited by a radio frequency generator and induces eddy currents in the conducting film. The resulting eddy currents are detected using the eddy current coil and the eddy current detector. The resultant eddy current sensing is indicative of sheet resistance that relates to film thickness. By providing both capacitance and eddy current sensing measurements, conducting film thickness may be quickly and accurately determined. Numerous other aspects are provided.

The present application claims priority from U.S. Provisional Patent Application Serial No. 60/371,267, filed Apr. 8, 2002, which is hereby incorporated by reference herein in its entirety.

### BACKGROUND OF THE INVENTION

1. Field of the Invention

The present invention relates to a sensor for the efficient inspection and measurement of objects such as semiconductor wafers upon which conducting films are deposited.

2. Description of the Related Art

In the semiconductor manufacturing process, conducting films often are deposited on semiconductor wafers, etched, and overlaid by additional conducting films. Quality and thickness of conducting films is important to the manufacturing process, and it is of particular interest to measure the thickness of conducting films quickly and accurately. Conducting films can serve, for example, as barrier, adhesion or seed layers. Each of these layers typically is composed of different materials, each material having different properties, including resistivity. Resistivity is an intrinsic property of a material defined as its resistance to current per unit length for a uniform cross section. Sheet resistance of a conducting film is defined as resistivity divided by the thickness of the film. Thus, by measuring sheet resistance, it is possible to measure conducting film thickness.

Conducting film thickness may be measured by inducing eddy currents in a conducting film and measuring the strength of those eddy currents. An eddy current sensor having a driver coil and a detector coil may be used to induce and measure the eddy currents. The driver coil is connected to a power source used to excite the coil at radio frequencies (e.g., and induce eddy currents in a conducting film). The detector coil is connected to circuitry for measuring the magnitude of the induced eddy currents.

The magnitude of the induced eddy currents relates to the strength of the magnetic field produced by the driver coil and to the sheet resistance of the conducting film. The strength of the magnetic field relates to the driver current, the physical characteristics of the driver coil including the number of turns and the impedance of the driver coil, and the distance between the eddy current sensor and the conducting film. Because the sheet resistance relates to the resistivity of the conducting film, the thickness of the conducting film, and the frequency of the magnetic field, sheet resistance may be used to indicate conducting film thickness.

Because the physical properties including resistivity of the conducting film are known, and the characteristics of the eddy current sensor coils are known, the conducting film thickness relates to the proximity of the eddy current sensor to the conducting film. Knowing the distance between the sensor and the film, the film thickness then may be determined. Techniques for measuring the distance from a sensor to a conducting surface are well known in the art. For example, U.S. Pat. No. 4,727,322 issued to Lonchampt et al. discloses an eddy current probe which is moved normal to an inspection surface using a mechanical positioning device providing a distance measurement. In U.S. Pat. No. 4,849,694 issued to Coates, an optical microscope objective lens is used to accurately position an eddy current probe. Further, in U.S. Pat. No. 5,525,903 issued to Mandl et al., the distance from an eddy current probe to a conducting surface is measured using an integral capacitance probe (e.g., a capacitance sensor disposed within an eddy current sensor).

Measuring the thickness of a conducting film requires two separate measurements. First the eddy current must be measured, and second, the distance from the sensor to the conducting film must be measured. Many prior art devices require that the measurements be made sequentially, often involving an interruption of the manufacturing process.

### SUMMARY OF THE INVENTION

The present invention discloses an apparatus, system, and method to overcome this deficiency and take all measurements necessary to determine conducting film thickness (e.g., simultaneously) while minimizing the disruption to the manufacturing process, thereby improving the quality and yield of the manufacturing process and shortening the manufacturing time. Accordingly, one feature of this invention is to provide a single sensor that will measure the thickness of a conducting film using eddy current measurements, with appropriate compensation for the proximity of the sensor to the film. Eddy current measurements typically may be made at a distance of a few microns to hundreds of microns from the film and cover an area of 1 to 2 square millimeters although other distances/areas may be employed. In order to use eddy current measurements for determining a sheet resistance, the distance between the sensor and the film must be known. Knowing the resistivity of the film material and the distance from the sensor to the film, the film thickness may be determined. Capacitance measurements are useful to determine the proximity of a sensor to a conducting film, and the inventive design enables both eddy current sensing and capacitance measurements to be taken sequentially or simultaneously by a single sensor.

In accordance with the invention, a capacitance probe and an eddy current coil are provided together. In one embodiment, an eddy current coil may be placed co-axially within a capacitance probe. The eddy current coil is connected to a radio frequency generator (for inducing eddy currents in a conducting film) and to an eddy current detector that measures the strength of the eddy currents generated in the conducting film. The capacitance probe is connected to circuitry for measuring the capacitance between the probe and the conducting film. The eddy current coil may be located within the capacitance probe to minimize interference between the two. Interference is increased when the capacitance probe is placed within the eddy current coil. Further, in at least one embodiment, the eddy current coil is oriented within the capacitance probe such that the magnetic axis is parallel to the surface of the conducting film. Still further, a ferrite core may be placed within the eddy current coil to increase the magnetic field strength generated by the eddy current coil.

In another embodiment, a capacitance sensor is mounted external to the eddy current sensor (e.g., alongside the eddy current sensor). Connections to the capacitance sensor and the eddy current sensor may remain the same as in the first embodiment.

In still a further embodiment, an array of eddy current—capacitance sensors may be used to measure the uniformity of a film's properties. In yet a further embodiment, a single such sensor may be used to measure the film thickness at various locations by effecting relative movement between the sensor and the film, by moving either the sensor, or the semiconductor wafer upon which a film is deposited, or both.

Other features and aspects of the present invention will become more fully apparent from the following detailed description, the appended claims and the accompanying drawings.

### BRIEF DESCRIPTION OF THE DRAWINGS

These and other features and benefits of the invention will be readily appreciated in light of the following detailed description of the preferred embodiments thereof, given by way of example only with reference to the accompanying drawings wherein:

FIG. 1 shows a first embodiment of the inventive sensor provided in accordance with the present invention;

FIG. 2 shows a cross section of the inventive sensor provided in accordance with the present invention;

FIG. 3 shows an inspection system using the inventive sensor of FIGS. 1 and 2; and

FIG. 4 shows an embodiment of an inventive sensor array according to the invention.

### DETAILED DESCRIPTION OF THE PREFERRED EMBODIMENTS

Preferred embodiments of the present invention will now be described with reference to the attached drawings, wherein identical elements are designated with like numerals.

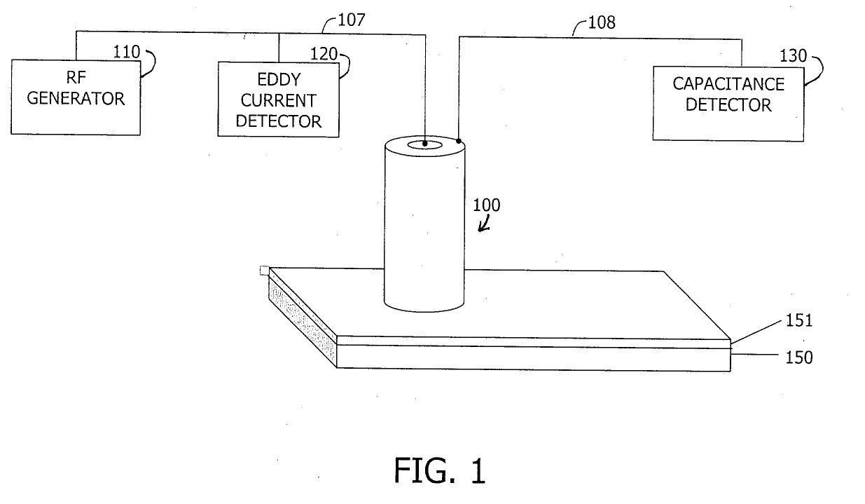

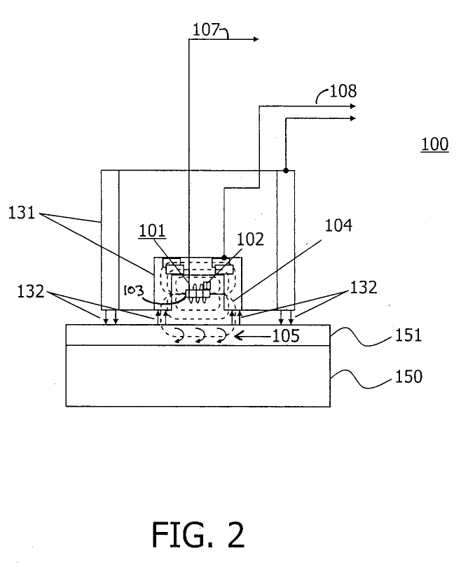

With reference to FIG. 1, an inventive eddy current-capacitance sensor 100 is provided that offers clear and distinct advantages over other sensors to measure conducting film thickness. In a typical installation, referring to FIG. 1, the sensor 100 may be positioned from a few microns to a few hundreds of microns over an object 150, such as a semiconductor wafer, a glass plate or any other substrate upon which a conducting film 151 has been deposited. An eddy current coil 101 having a ferrite core 103 as shown in FIG. 2 is energized by a radio frequency generator 110 using conductor 107. The eddy current coil 101 induces eddy currents 105 in the conducting film 151 that are then detected by an eddy current detector 120. Measurements taken by the eddy current detector 120 relate to the sheet resistance of the conducting film 151, and in the case of constant sheet resistance, the thickness of the film. Changes in capacitance which relate to the distance of the sensor 100 to the conducting film 151 are sensed by a capacitance detector 130 using conductor 108.

As generally illustrated in FIG. 2, a cross sectional view of one construction according to the invention, the eddy current coil 101 includes the ferrite core 103 having a predetermined number of turns in a winding 102. The winding 102 is excited by the radio frequency generator 110 (FIG. 1) operating at an appropriate frequency for the characteristics of the eddy current coil 101. The eddy current coil 101 generates a magnetic field 104 that penetrates the conductive film 151, and this magnetic field 104 further produces eddy currents 105 within the conductive film.

In general, a magnetic field will generate currents that are perpendicular to the magnetic lines of force. In at least one embodiment of the invention, the eddy current coil 101 of the present invention is disposed having a magnetic axis parallel to the surface of the conductive film 151 thereby generating eddy currents in the conductive film 151 that are perpendicular to the surface of the film 151. The eddy current coil 101 is also connected to the eddy current detector 120 for detecting eddy currents 105.

The sensor 100 also measures capacitance that relates to the proximity of the sensor to the conducting film 151. Voltage is applied to capacitor electrodes 131 thereby generating an electric field 132 between the electrodes 131 and the conducting film 151. The capacitance varies inversely with the distance between the conducting film 151 and the eddy capacitance sensor 100. The capacitance detection circuitry 130 senses the capacitance and from this capacitance, the distance between the sensor 100 and the film 151 may be determined.

Exemplary dimensions for the sensor 100 shown in FIG. 2 are 10 mm in length (height) and 3 mm in diameter though it is within the contemplation of the invention to vary the dimensions as needed, depending upon the application.

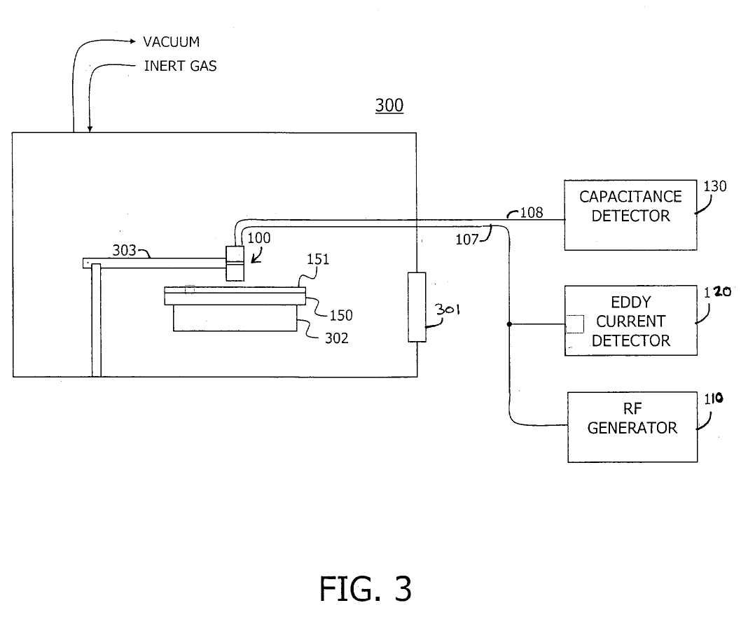

FIG. 3 shows one example of the inventive sensor 100 in the context of a manufacturing process, wherein sensor measurements can be taken in situ on an object, without removing the object from the manufacturing process. In FIG. 3, the object 150, such as a semiconductor wafer having the conducting film 151 disposed thereon, is placed in an inspection chamber 300 through an air lock 301. The object 150 is placed on a positioning turntable 302 so that the object 150 may be rotated through 360 degrees if desired. Other object support stages may be employed, such as a translatable support stage. Positioning the object 150 on the positioning turntable 302 may be performed, for example, by robotic devices (not shown). The sensor 100 is mounted on a positioning arm 303 that positions the sensor 100 at the correct distance from the object 150 and in some embodiments has the ability to position the sensor 100 over any part of the object 150 (and hence over any part of the conducting film 151). Various mechanisms to effect relative movement/position between the sensor 100 and the object 150 are well known to a skilled artisan. It is envisioned that these mechanisms will adjust the proximity (e.g., height) of the sensor 100 to the conducting film 151 and/or adjust the angular or translational position of the positioning arm 303 with respect to the object 150. Any point on the conducting film 151 may be inspected by providing appropriate relative movement between the object 150 and the sensor 100. This relative movement may be effected by moving the object 150 with the turntable 302; moving the sensor 100 with arm 303; or both. Further, a relative tilt may be provided between the sensor 100 and the object 150 such that the sensor axis is not perpendicular to the surface of the object 150.

It may be desirable for the inspection chamber 300 to be used for another process of wafer manufacture such as a cool-down, an anneal, or a metal deposition step, etc., wherein eddy-capacitance inspection may proceed before, along with or after the other process, thereby reducing set-up time and increasing overall throughput.

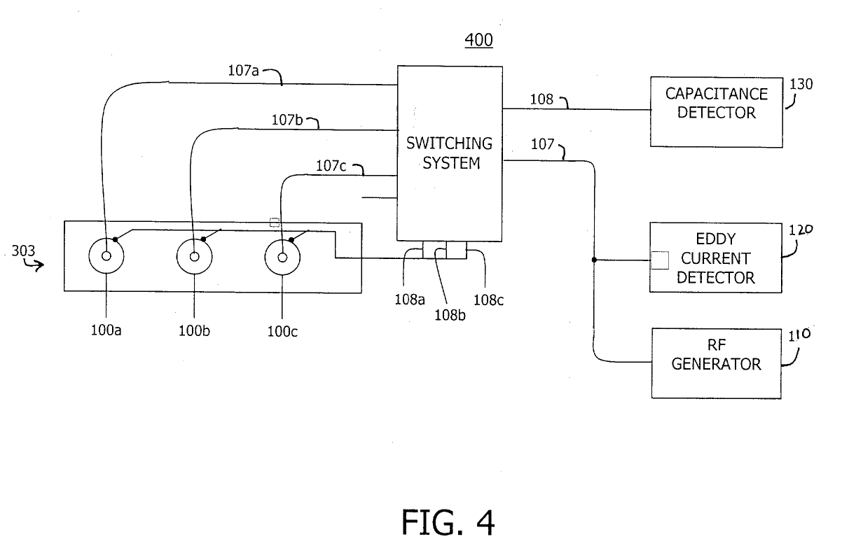

FIG. 4 shows an array of the inventive sensors 100 that may monitor several locations on a wafer or other substrate. In FIG. 4, several sensors 100a-100c are mounted on a positioning arm 303. Fewer or more than 3 sensors may be employed. The positioning arm 303 may be any configuration that comports with a desired inspection pattern. Each of the sensors 100a-100c is connected to a switching system 400 using a plurality of conductors 107a-107c such that the switching system 400 may quickly connect an individual sensor 100a-100c to the capacitance detector 130, the eddy current detector 120 and the RF generator 110 either sequentially or in a predetermined sequence. In such a manner, several locations on the object to be inspected may be quickly and/or selectively examined. Alternatively, a separate capacitance detector, eddy current detector and/or RF generator may be employed for each sensor 100a-100c (e.g., to allow for simultaneous eddy-current-capacitance measurements at two or more of the sensors 100a-c). Any layout of sensors may be employed (e.g., a linear array, a circular array, a rectangular array, etc.).

The foregoing description discloses only exemplary embodiments of the invention. Modifications of the above disclosed apparatus and method which fall within the scope of the invention will be readily apparent to those of ordinary skill in the art. For instance, in a less preferred embodiment, the capacitance probe may be positioned along-side or inside the eddy current coil, and/or the eddy current coil may have a magnetic axis perpendicular to the surface of a thin film. Film thickness measurements may be made at any distance from and at any location of a thin film.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

The invention claimed is:

1. A sensor for use in inspection of objects, said sensor comprising:
a capacitance probe, and
an eddy current coil disposed co-axially within said capacitance probe.

2. A sensor as claimed in claim 1, wherein said object is a semiconductor wafer having a conducting film deposited thereon.

3. A sensor as claimed in claim 2, wherein said sensor measures a thickness of said film.

4. A sensor as claimed in claim 1, wherein said eddy current coil further comprises a ferrite core.

5. A sensor as claimed in claim 1, wherein said eddy current coil has its magnetic axis disposed parallel to said object.

6. A sensor for use in inspection of objects, said sensor comprising:
a capacitance probe, and
an eddy current coil having a magnetic axis disposed parallel to said object.

7. A sensor as claimed in claim 6, wherein said object is a semiconductor wafer having a conducting film deposited thereon.

8. A sensor as claimed in claim 7, wherein said sensor measures a thickness of said film.

9. A sensor as claimed in claim 6, wherein said eddy current coil further comprises a ferrite core.

10. A sensor as claimed in claim 6, wherein said eddy current coil is disposed co-axially within said capacitance probe.

11. A method of inspecting objects, said method comprising:
detecting an eddy current induced in an object by an eddy current coil disposed co-axially within a capacitance probe of a sensor, said sensor having a position relative to said object; and
measuring a distance between said sensor and said object using said capacitance probe.

12. The method of claim 11, wherein said object is a semiconductor wafer having a conducting film deposited thereon.

13. The method of claim 11, wherein said eddy current coil has a magnetic axis parallel to said object being inspected.

14. The method of claim 11, further comprising providing relative movement between said object and said sensor.

15. The method of claim 14, wherein said sensor is moved.

16. The method of claim 15, wherein said sensor is tilted.

17. The method of claim 14, wherein said object is moved.

18. The method of claim 11, wherein said object is inspected using more than one said sensor.

19. A method of inspecting objects, said method comprising:
detecting an eddy current induced in an object by an eddy current coil of a sensor, the eddy current coil having a magnetic axis disposed parallel to said object, said sensor having a position relative to said object; and
measuring a distance between said sensor and said object using a capacitance probe of said sensor.

20. The method of claim 19, wherein said object is a semiconductor wafer having a conducting film deposited thereon.

21. The method of claim 19, wherein said eddy current coil is disposed within said capacitance probe.

22. The method of claim 19, further comprising providing relative movement between said object and said sensor.

23. The method of claim 22, wherein said sensor is moved.

24. The method of claim 23, wherein said sensor is tilted.

25. The method of claim 22, wherein said object is moved.

26. The method of claim 19, wherein said object is inspected using more than one said sensor.

27. An object inspection system comprising:
a sensor having:
a capacitance probe, and
an eddy current coil connected to a radio frequency generator, and to an eddy current detector, said eddy current coil being disposed within said capacitance probe, and
an inspection chamber housing said sensor and adapted to house an object during inspection.

28. An inspection system as claimed in claim 27, wherein said object is a wafer having a film deposited thereon.

29. An inspection system as claimed in claim 28, wherein said sensor measures a thickness of said film.

30. An inspection system as claimed in claim 27, wherein said eddy current coil has a magnetic axis disposed parallel to said object.

31. An inspection system as claimed in claim 27, wherein said object is a wafer, wherein said inspection chamber is further adapted to perform a wafer manufacturing process, said system further comprising positioning means for providing relative movement between said sensor and said wafer, and an airlock for inserting said wafer into said inspection chamber.

32. An inspection system as claimed in claim 31, wherein said positioning means further comprises a positioning arm on which said sensor is disposed.

33. An inspection system as claimed in claim 31, wherein said positioning means further comprises an apparatus for providing a relative tilt angle between said sensor and said object.

34. An inspection system as claimed in claim 32, wherein said positioning means further comprises a positioning turntable on which said object is disposed.

35. An inspection system as claimed in claim 27, wherein said system comprises more than one said sensor.

36. An object inspection system comprising:
a sensor having:
a capacitance probe, and
an eddy current coil connected to a radio frequency generator, and to an eddy current detector, said eddy current coil having a magnetic axis disposed parallel to an object being inspected within the object inspection system, and
an inspection chamber housing said sensor and said object during inspection.

37. An inspection system as claimed in claim 36, wherein said object is a wafer having a film deposited thereon.

38. An inspection system as claimed in claim 37 wherein said sensor measures a thickness of said film.

39. An inspection system as claimed in claim 36, wherein said eddy current coil is axially disposed within said capacitance probe.

40. An inspection system as claimed in claim 36, wherein said object is a wafer, wherein said inspection chamber is further adapted to perform a wafer manufacturing process, said system further comprising a positioning means for providing relative movement between said sensor and said wafer, and an airlock for inserting said wafer into said inspection chamber.

41. An inspection system as claimed in claim 40, wherein said positioning means further comprises a positioning arm on which said sensor is disposed.

42. An inspection system as claimed in claim 41, wherein said positioning means further comprises an apparatus for tilting said sensor at an angle with respect to said object.

43. An inspection system as claimed in claim 41, wherein said positioning means further comprises a positioning turntable on which said object is disposed.

44. An inspection system as claimed in claim 36, wherein said system comprises more than one said sensor.
